(19) United States
(12) Patent Application Publication
(10) Pub. No.: US 2026/0047281 A1
(43) Pub. Date: Feb. 12, 2026

(54) DISPLAY DEVICE

(71) Applicant: Japan Display Inc., Tokyo (JP)

(72) Inventors: Kaichi FUKUDA, Tokyo (JP); Hiroshi TABATAKE, Tokyo (JP); Kazuyuki HARADA, Tokyo (JP)

(73) Assignee: Japan Display Inc., Tokyo (JP)

(21) Appl. No.: 19/291,663

(22) Filed: Aug. 6, 2025

(30) Foreign Application Priority Data
Aug. 9, 2024 (JP) 2024-134201

(51) Int. Cl. H10K 59/122; H10K 59/35; H10K 59/80

(52) U.S. Cl. CPC H10K 59/122; H10K 59/353; H10K 59/871

(57) ABSTRACT

According to one embodiment, a display device includes first and second subpixels, a partition including a first segment surrounding the first subpixel and a second segment surrounding the second subpixel, a first stacked film in the first subpixel, a second stacked film in the second subpixel, a first sealing layer formed of an inorganic insulating material and covering the first stacked film, and a second sealing layer formed of an inorganic insulating material and covering the second stacked film. The first segment and the segment are separated from each other by a slit. Further, the first sealing layer overlaps at least part of the slit in plan view.

### CROSS-REFERENCE TO RELATED APPLICATION

This application is based upon and claims the benefit of priority from Japanese Patent Application No. 2024-134201, filed Aug. 9, 2024, the entire contents of which are incorporated herein by reference.

### FIELD

Embodiments described herein relate generally to a display device.

### BACKGROUND

Recently, display devices with organic light-emitting diodes (OLED) applied thereto as display elements have been put into practical use. In this type of display devices, a technique which can improve yield is required.

### BRIEF DESCRIPTION OF THE DRAWINGS

FIG. 1 is a view showing a configuration example of a display device according to the first embodiment.

FIG. 2 is a schematic plan view showing an example of the layout of subpixels according to the first embodiment.

FIG. 3 is a schematic cross-sectional view of the display device along the III-III line of FIG. 2.

FIG. 4 is a schematic cross-sectional view showing the vicinity of a boundary between subpixels in FIG. 2 in an enlarged manner.

FIG. 5 is a schematic cross-sectional view showing the vicinity of a boundary between subpixels in FIG. 2 in an enlarged manner.

FIG. 6 is a flowchart showing an example of a manufacturing method of the display device.

FIG. 7A is a schematic cross-sectional view showing a first example of a formation method of a partition.

FIG. 7B is a schematic cross-sectional view showing a process following FIG. 7A.

FIG. 7C is a schematic cross-sectional view showing a process following FIG. 7B.

FIG. 7D is a schematic cross-sectional view showing a process following FIG. 7C.

FIG. 7E is a schematic cross-sectional view

showing a process following FIG. 7D.

FIG. 7F is a schematic cross-sectional view showing a process following FIG. 7E.

FIG. 7G is a schematic cross-sectional view showing a process following FIG. 7F.

FIG. 7H is a schematic cross-sectional view showing a process following FIG. 7G.

FIG. 7I is a schematic cross-sectional view showing a process following FIG. 7H.

FIG. 8A is a schematic cross-sectional view showing a second example of the formation method of the partition.

FIG. 8B is a schematic cross-sectional view showing a process following FIG. 8A.

FIG. 8C is a schematic cross-sectional view showing a process following FIG. 8B.

FIG. 8D is a schematic cross-sectional view showing a process following FIG. 8C.

FIG. 8E is a schematic cross-sectional view showing a process following FIG. 8D.

FIG. 8F is a schematic cross-sectional view showing a process following FIG. 8E.

FIG. 8G is a schematic cross-sectional view showing a process following FIG. 8F.

FIG. 8H is a schematic cross-sectional view showing a process following FIG. 8G.

FIG. 8I is a schematic cross-sectional view showing a process following FIG. 8H.

FIG. 8J is a schematic cross-sectional view showing a process following FIG. 8I.

FIG. 8K is a schematic cross-sectional view showing a process following FIG. 8J.

FIG. 8L is a schematic cross-sectional view showing a process following FIG. 8K.

FIG. 9A is a schematic cross-sectional view showing a process of forming a pixel aperture.

FIG. 9B is a schematic cross-sectional view showing a process following FIG. 9A.

FIG. 9C is a schematic cross-sectional view showing a process of forming a display element.

FIG. 9D is a schematic cross-sectional view showing a process following FIG. 9C.

FIG. 9E is a schematic cross-sectional view showing a process following FIG. 9D.

FIG. 9F is a schematic cross-sectional view showing a process following FIG. 9E.

FIG. 10 is a schematic cross-sectional view showing the configuration of a comparative example.

FIG. 11 is a schematic plan view of a display area of a display device according to the second embodiment.

FIG. 12 is a schematic plan view of a display area of a display device according to the third embodiment.

FIG. 13 is a schematic cross-sectional view showing a display device along the XIII-XIII line of FIG. 12.

FIG. 14 is a schematic plan view of a display area of the display device according to the fourth embodiment.

FIG. 15 is a schematic plan view of a display

area of the display device according to the fifth embodiment.

FIG. 16 is a schematic cross-sectional view of a display device along the XVI-XVI line of FIG. 15.

FIG. 17 is a schematic cross-sectional view

of a display device along the XVII-XVII line of FIG. 15.

FIG. 18 is a schematic plan view of a display area of a display device according to the sixth embodiment.

### DETAILED DESCRIPTION

In general, according to one embodiment, a display device includes a first subpixel, a second subpixel, a partition including a first segment surrounding the first subpixel and a second segment surrounding the second subpixel, a first stacked film provided in the first subpixel and including an electrode electrically connected to the first segment, a second stacked film provided in the second subpixel and including an electrode electrically connected to the second segment, a first sealing layer formed of an inorganic insulating material and covering the first stacked film, and a second sealing layer formed of an inorganic insulating material and covering the second stacked film. The first segment and the second segment are separated from each other by a slit. Further, the first sealing layer overlaps at least part of the slit in plan view.

According to another viewpoint of the embodiments, the first sealing layer has a first end portion located inside the slit. Further, a first gap is formed under the first end portion.

These configurations can improve the yield of the display device.

Embodiments will be described hereinafter with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

### First Embodiment

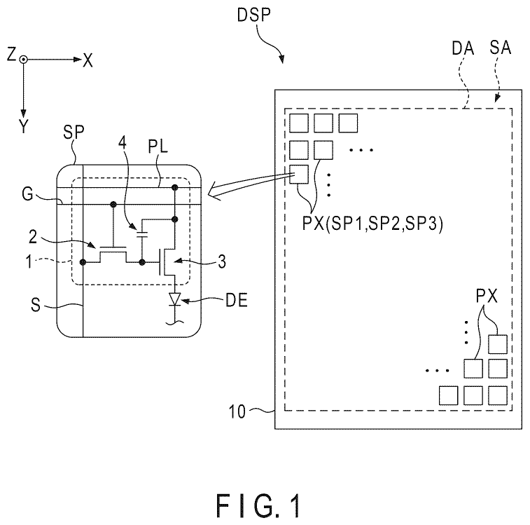

FIG. 1 is a view showing a configuration example of a display device DSP of the first embodiment. The display device DSP comprises an insulating substrate 10. The substrate 10 has a display area DA, which displays an image and a surrounding area SA around the display area DA. The substrate 10 may be glass or a resinous film having flexibility.

In the present embodiment, the substrate 10 has a rectangular shape in plan view. The shape of the substrate 10 in plan view is not limited to a rectangle and may be another shape such as a square, a circle or an oval.

The display area DA comprises a plurality of pixels PX arranged in a matrix in the X-direction and the Y-direction. Each pixel PX includes a plurality of subpixels SP which display different colors. The present embodiment assumes a case where each pixel PX includes a blue subpixel SP1 (the first subpixel), a green subpixel SP2 (the second subpixel), and a red subpixel SP3 (the third subpixel). However, each pixel PX may include a subpixel SP which exhibits another color such as white in addition to the subpixels SP1, SP2, and SP3 or instead of one of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

The display area DA has a plurality of scanning lines G supplying the pixel circuit 1 of each subpixel SP with scanning signals, a plurality of signal lines S supplying the pixel circuit 1 of each subpixel SP with video signals, and a plurality of power lines PL. In the example of FIG. 1, the scanning lines G and the power lines PL extend in the X-direction, and the signal lines S extend in the Y-direction.

The gate electrode of the pixel switch 2 is connected to the scanning line G. A source electrode of the pixel switch 2 is connected to the signal line S. A drain electrode of the pixel switch 2 is connected to a gate electrode of the drive transistor 3 and the capacitor 4. A source electrode of the drive transistor 3 is connected to the power line PL and the capacitor 4. The drain electrode of the drive transistor 3 is connected to the display element DE.

The configuration of the pixel circuit 1 is not limited to the example of the figure. For example, the pixel circuit 1 may comprise more thin-film transistors and capacitors.

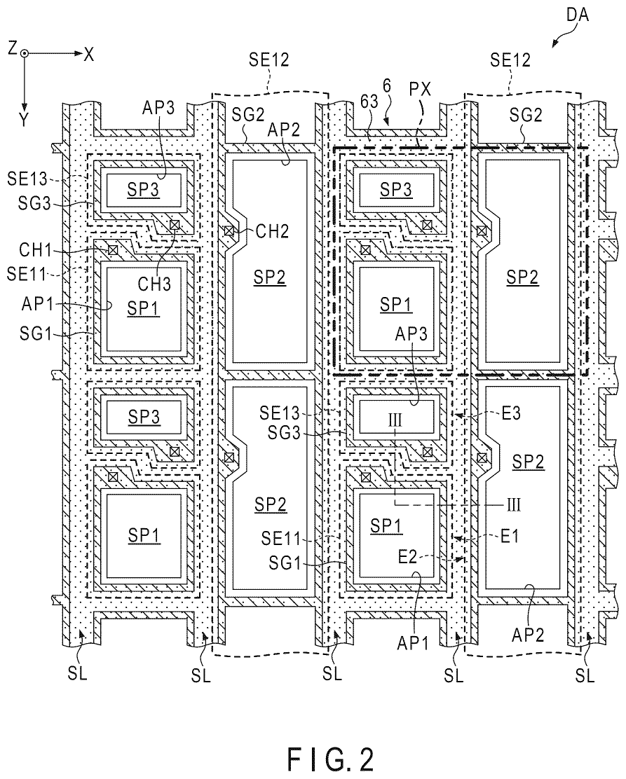

FIG. 2 is a schematic plan view showing an example of the layout of the subpixels SP1, SP2, and SP3. The example of FIG. 2 shows areas corresponding to four pixels PX. In each pixel PX, the subpixels SP1 and SP3 are arranged with the subpixel SP2 in the X-direction. Further, the subpixels SP1 and SP3 are arranged in the Y-direction.

When the subpixels SP1, SP2, and SP3 are arranged in this layout, in the display area DA, a column in which the subpixels SP1 and SP3 are alternately arranged in the Y-direction and a column in which the plurality of subpixels SP2 are repeatedly arranged in the Y-direction are formed. These columns are alternately arranged in the X-direction. The layout of the subpixels SP1, SP2, and SP3 is not limited to the example of FIG. 2.

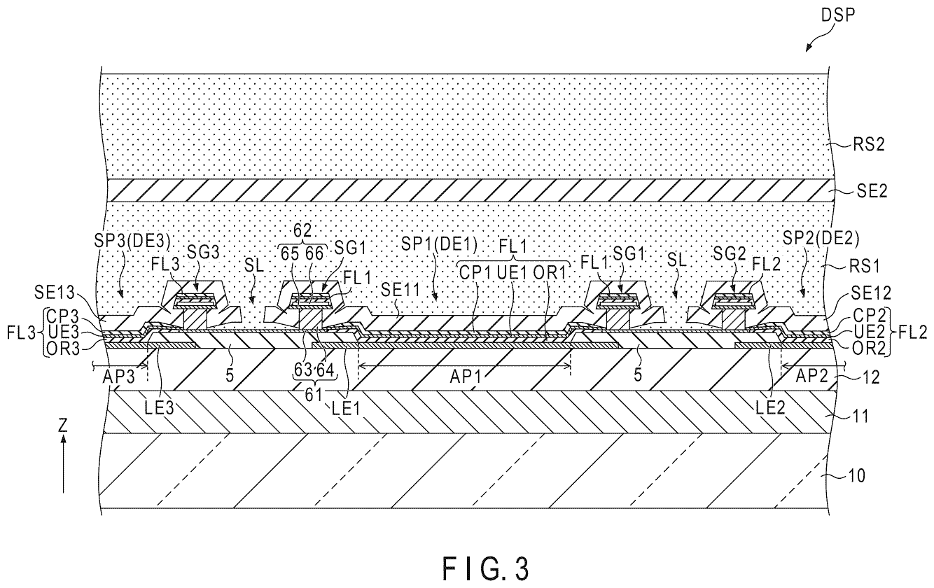

The pixel apertures AP1, AP2, and AP3 are formed in the subpixels SP1, SP2, and SP3. These pixel apertures AP1, AP2, and AP3 are provided in a rib layer 5 (for example, refer to FIG. 3). In the example of FIG. 2, the pixel aperture AP1 is greater than the pixel aperture AP3, and the pixel aperture AP2 is greater than the pixel aperture AP1. Thus, among the subpixels SP1, SP2, and SP3, the aperture ratio of the subpixel SP2 is the greatest, and the aperture ratio of the subpixel SP3 is the least. The size of each of the pixel apertures AP1, AP2, and AP3 is not limited to this example. For example, at least two of the pixel apertures AP1, AP2, and AP3 may have the same size.

A partition 6 is provided in the display area DA. FIG. 2 indicates the partition 6 by a dotted pattern. The area indicated by the dotted pattern is the area where a bottom layer 63 described later is provided as well. The partition 6 has a grating shape surrounding the subpixels SP1, SP2, and SP3.

The partition 6 has a plurality of segments SG1, SG2, and SG3 (the first to third segments). FIG. 2 indicates the segments SG1, SG2, and SG3 by hatch lines. The segment SG1 surrounds one subpixel SP1. In the same manner, the segments SG3 surrounds one subpixel SP3. In contrast, the segment SG2 surrounds a plurality of subpixels SP2 arranged in the Y-direction.

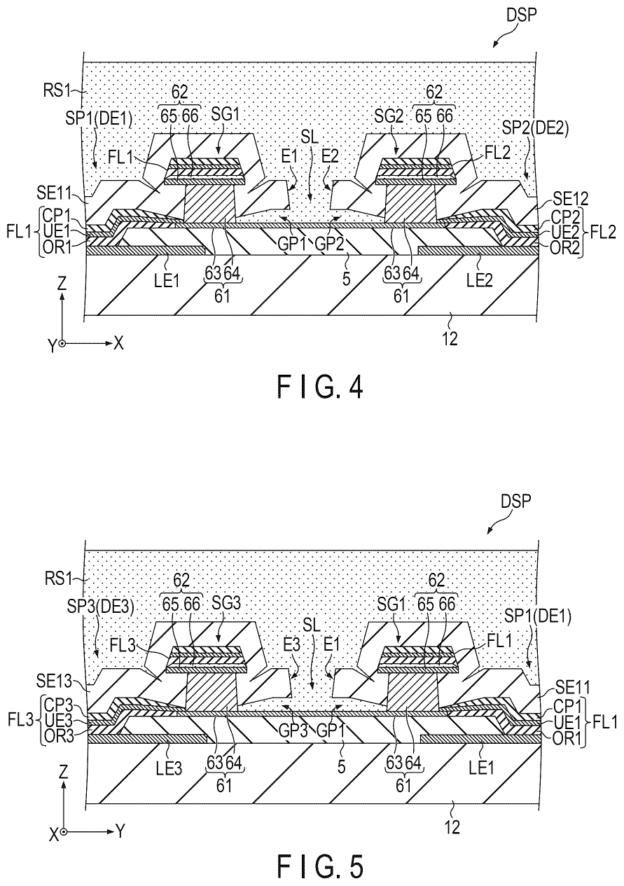

A slit SL is formed between the segments SG1, SG2, and SG3. The slit SL separates a stem layer 64 and an upper portion 62 each constituting the segments SG1, SG2, and SG3. This configuration is shown in FIG. 3 to FIG. 4 in detail. In the present embodiment, the bottom layer 63 overlaps the segments SG1, SG2, and SG3 and the slit SL in plan view. The slit SL extends in the Y-direction between the segments SG1 and SG2 and between the segments SG2 and SG3. Further, the slit SL extends in the X-direction between the segments SG1 and SG3. In the present embodiment, each of the segments SG1 and SG3 is surrounded by the slit SL.

Sealing layers SE11, SE12, and SE13 (the first to third sealing layers) are provided in the subpixels SP1, SP2, and SP3, respectively. The sealing layer SE11 overlaps the subpixel SP1 and the segment SG1. The sealing layer SE12 overlaps the plurality of subpixels SP2 and the segments SG2 arranged in the Y-direction. The sealing layer SE13 overlaps the subpixel SP3 and the segment SG3.

The sealing layers SE11, SE12, and SE13 overlap at least part of the slit SL. In the example of FIG. 2, an end portion E1 of the sealing layer SE11 is located in the slit SL over its whole circumference. An end portion E3 of the sealing layer SE13 is located in the slit SL over its whole circumference. Further, an end portion E2 extending in the Y-direction of the sealing layer SE12 is entirely located in the slit SL.

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, the scanning lines G, the signal lines S, and the power line PL shown in FIG. 1. The circuit layer 11 is covered with an organic insulating layer 12. The organic insulating layer 12 functions as a planarization film, which planarizes irregularities formed by the circuit layer 11.

The subpixels SP1, SP2, and SP3 respectively have lower electrodes LE1, LE2, and LE3 provided on the organic insulating layer 12. The lower electrodes LE1, LE2, and LE3 are connected to the respective pixel circuits 1 of the circuit layer 11 through respective contact holes CH1, CH2, and CH3 (refer to FIG. 2) provided in the organic insulating layer 12. The contact holes CH1, CH2, and CH3 are provided at positions respectively overlapping the segments SG1, SG2, and SG3 in plan view.

End portions of the lower electrodes LE1, LE2, and LE3 are covered with the rib layer 5. The rib layer 5 has the pixel apertures AP1, AP2, and AP3. The lower electrodes LE1, LE2, and LE3 are exposed from the rib layer 5 through the respective pixel apertures AP1, AP2, and AP3.

The partition 6 comprises the bottom layer 63 having conductivity and provided on the rib layer 5. The segments SG1, SG2, and SG3 of the partition 6 are provided on the bottom layer 63. The segments SG1, SG2, and SG3 have a stem layer 64 having conductivity and located on the bottom layer 63 and an upper portion 62 provided on the stem layer 64. The bottom layer 63 and the stem layer 64 constitute a lower portion 61 of the partition 6.

In the example of FIG. 3, the upper portion 62 has a first top layer 65 and a second top layer 66. The first top layer 65 is provided on the stem layer 64. The second top layer 66 is provided on the first top layer 65.

The upper portion 62 has the width greater than that of the stem layer 64 in each of the segments SG1, SG2, and SG3. Thus, the both end portions of the upper portion 62 protrude relative to the side surfaces of the stem layer 64. That is, the segments SG1, SG2, and SG3 have an overhang shape in which the both end portions of the upper portion 62 protrude relative to the side surfaces of the stem layer 64.

The subpixels SP1, SP2, and SP3 comprise respective stacked films FL1, FL2, and FL3 (the first to third stacked films). The stacked film FL1 includes, an organic layer OR1 contacting the lower electrode LE1 through the pixel aperture AP1, an upper electrode UE1 covering the organic layer OR1, and a cap layer CP1 covering the upper electrode UE1. The stacked film FL2 includes, an organic layer OR2 contacting the lower electrode LE2 through the pixel aperture AP2, an upper electrode UE2 covering the organic layer OR2, and a cap layer CP2 covering the upper electrode UE2. The stacked film FL3 includes, an organic layer OR3 contacting the lower electrode LE3 through the pixel aperture AP3, an upper electrode UE3 covering the organic layer OR3, and a cap layer CP3 covering the upper electrode UE3. The upper electrodes UE1, UE2, and UE3 are electrically connected to the respective segments SG1, SG2, and SG3. For example, the upper electrodes UE1, UE2, and UE3 contact the bottom layer 63 under the segments SG1, SG2, and SG3. The upper electrodes UE1, UE2, and UE3 may further contact the stem layer 64 of the segments SG1, SG2, and SG3.

The lower electrode LE1, the upper electrode UE1, and the organic layer OR1 constitute a display element DE1 of the subpixel SP1. The lower electrode LE2, the upper electrode UE2, and the organic layer OR2 constitute a display element DE2 of the subpixel SP2. The lower electrode LE3, the upper electrode UE3, and the organic layer OR3 constitute a display element DE3 of the subpixel SP3.

The subpixels SP1, SP2, and SP3 respectively comprise the sealing layers SE11, SE12, and SE13. The sealing layer SE11 continuously covers the stacked film FL1 and the segment SG1. The sealing layer SE12 continuously covers the stacked film FL2 and the segment SG2. The sealing layer SE13 continuously covers the stacked film FL3 and the segment SG3.

In the example of FIG. 3, the stacked films FL1, FL2, and FL3 are provided on the respective segments SG1, SG2, and SG3 as well. These stacked films FL1, FL2, and FL3 are covered with the respective sealing layers SE11, SE12, and SE13.

The sealing layers SE11, SE12, and SE13 are covered with a resin layer RS1. The resin layer RS1 is covered with the sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a touch panel, a protective film, or a cover glass may be further provided above the resin layer RS2. This cover member may be attached to the resin layer RS2 via, for example, an adhesive layer such as an optical clear adhesive (OCA). The electrodes that constitute the touch panel may be provided on the sealing layer SE2.

The electrodes that constitute the touch panel may be provided on the sealing layer SE2. Further, color filters respectively corresponding to the colors of the subpixels SP1, SP2, and SP3 may be respectively provided above the display elements DE1, DE2, and DE3.

The organic insulating layer 12 is formed of an organic insulating material such as a polyimide.

Each of the rib layer 5 and the sealing layers SE11, SE12, SE13, and SE2 is formed of an inorganic insulating material such as a silicon nitride (SiNx), a silicon oxide (SiOx), or a silicon oxynitride (SiON). For example, the rib layer 5 is formed of a silicon oxynitride, and each of the sealing layers SE11, SE12, SE13, and SE2 is formed of a silicon nitride. Each of the resin layers RS1 and RS2 is formed of, for example, a resinous material (organic insulating materials) such as an epoxy resin or an acrylic resin.

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is composed of a plurality of thin films including a light emitting layer. As an example, the organic layers OR1, OR2, and OR3 have a structure in which a hole-injection layer, a hole-transport layer, an electron blocking layer, a light emitting layer, a hole blocking layer, an electron-transport layer, and an electron-injection layer are stacked in this order in the Z-direction. The organic layers OR1, OR2, and OR3 each may have other structures such as a tandem structure including a plurality of light emitting layers.

The cap layers CP1, CP2, and CP3 function as optical adjustment layers which improve the extraction efficiency of the light emitted from the organic layers OR1, OR2, and OR3, respectively. These cap layers CP1, CP2, and CP3 may have a stacked layer structure in which, for example, a plurality of transparent layers with different refractive indexes are stacked. At least one of the cap layers CP1, CP2, and CP3 may be omitted. The segments SG1, SG2, and SG3 and the bottom

layer 63 of the partition 6 are supplied with common voltage. This common voltage is supplied to each of the upper electrodes UE1, UE2, and UE3 that contact at least one of the bottom layer 63 and the stem layer 64. The lower electrodes LE1, LE2, and LE3 are supplied with pixel voltages according to the video signals of the signal lines S through the respective pixel circuits 1 provided in the subpixels SP1, SP2, and SP3.

The organic layers OR1, OR2, and OR3 emit light in response to the application of a voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2, and OR3 may emit light in the same color (for example, white). In this case, the display device DSP may comprise a color filter that converts the light emitted from the light emitting layers into light in the colors corresponding to those of the subpixels SP1, SP2, and SP3. In addition, the display device DSP may comprise a layer including quantum dots that are excited by the light emitted from the light emitting layers to generate the light in the colors corresponding to those of the subpixels SP1, SP2, and SP3.

For example, the bottom layer 63 and the stem layer 64 are formed of a metal material. For the metal material of the bottom layer 63, for example, molybdenum (Mo), titanium (Ti), a titanium nitride (TiN), a molybdenum-tungsten alloy (MoW), or a molybdenum-niobium alloy (MoNb) can be used. For the metal material of the stem layer 64, for example, aluminum (Al), an aluminum-neodymium alloy (AlNd), an aluminum-yttrium alloy (AlY), or an aluminum-silicon alloy (AlSi) can be used. For example, at least one of the bottom layer 63 and the stem layer 64 may have a stacked layer structure in which a plurality of layers are stacked. The stem layer 64 may include a layer formed of an insulating material. Further, as cases different from the preset embodiment where the lower portion 61 includes the bottom layer 63 and the stem layer 64, the lower portion 61 may have a single layer structure formed of a conductive material.

For example, the first top layer 65 is formed of a metal material and the second top layer 66 is formed of a transparent conductive oxide. For the metal material of the first top layer 65, for example, titanium, a titanium nitride, molybdenum, tungsten, a molybdenum-tungsten alloy, or a molybdenum-niobium alloy may be used. For the conductive oxide material of the second top layer 66, for example, an indium tin oxide (ITO), an indium zinc oxide (IZO), or an indium gallium zinc oxide (IGZO) may be used. The upper portion 62 may have a single-layer structure formed of a specific material. The upper portion 62 may further include a layer formed of an insulating material.

FIG. 4 is a schematic cross-sectional view showing the vicinity of a boundary between the subpixels SP1 and SP2 in FIG. 2 in an enlarged manner.

FIG. 5 is a schematic cross-sectional view showing the vicinity of a boundary between the subpixels SP1 and SP3 in FIG. 2 in an enlarged manner.

As shown in FIG. 4, the bottom layer 63 is provided from the position under the segment SG1 to the position under the segment SG2 and is not separated by the slit SL between the segments SG1 and SG2. In the slit SL between the segments SG1 and SG2, the stem layer 64 and the upper portion 62 of the segment SG1 are spaced apart from the stem layer 64 and the upper portion 62 of the segment SG2.

As shown in FIG. 5, the bottom layer 63 is provided from the position under the segment SG1 to the position under the segment SG3 and is not separated by the slit SL between the segments SG1 and SG3. In the slit SL between the segments SG1 and SG3, the stem layer 64 and the upper portion 62 of the segment SG1 are spaced apart from the stem layer 64 and the upper portion 62 of the segment SG3.

As shown in FIG. 4, the end portion of the bottom layer 63 protrudes relative to the side surface of the stem layer 64 of the segment SG1 toward the subpixel SP1 side. Similarly, the end portion of the bottom layer 63 protrudes relative to the side surface of the stem layer 64 of the segment SG2 toward the subpixel SP2 side. As shown in FIG. 5, the end portion of the bottom layer 63 protrudes relative to the side surface of the stem layer 64 of the segment SG3 toward the subpixel SP3 side.

The both end portions of the upper portion 62 protrude relative to both side surfaces of the stem layer 64 in each of the segments SG1, SG2, and SG3. In the segment SG1 in FIG. 4, the protrusion length on the subpixel SP1 side of the end portion of the upper portion 62 is greater than the protrusion length on the slit SL side of the end portion of the upper portion 62. Similarly, in the segment SG2 in FIG. 4, the protrusion length on the subpixel SP2 side of the end portion of the upper portion 62 is greater than the protrusion length on the slit SL side of the end portion of the upper portion 62. In the segment SG3 in FIG. 5 as well, the protrusion length on the subpixel SP3 side of the end portion of the upper portion 62 is greater than the protrusion length on the slit SL side of the end portion of the upper portion 62. The configuration is not limited to these examples, the protruding lengths of the both end portions of the upper portion 62 may be the same in each of the segments SG1, SG2, and SG3.

As shown in FIG. 4, the end portions E1 and E2 of the respective sealing layers SE11 and SE12 are located in the slit SL. In the example of FIG. 4, the end portions E1 and E2 are spaced apart from each other in the X-direction. As another example, the end portions E1 and E2 may contact.

As shown in FIG. 5, the end portions E1 and E3 of the respective sealing layers SE11 and SE13 are located in the slit SL. In the example of FIG. 5, the end portions E1 and E3 are spaced apart from each other in the X-direction. As another example, the end portions E1 and E3 may contact.

Gaps GP1, GP2, and GP3 (the first to third gaps) are formed under the respective end portions E1, E2, and E3. The gaps GP1, GP2, and GP3 in the present embodiment respectively correspond to spaces between the respective sealing layers SE11, SE12, and SE13 and the bottom layer 63.

In the examples of FIG. 4 and FIG. 5, the gaps GP1, GP2, and GP3 are entirely filled with the resin layer RS1. As another example, part of the gaps GP1, GP2, and GP3 may be filled with the resin layer RS1, and the remaining part may be cavity. As still another example, the respective stacked films FL1, FL2, and FL3 may be provided in at least part of the gaps GP1, GP2, and GP3.

The following describes an example of the manufacturing method of the display device DSP.

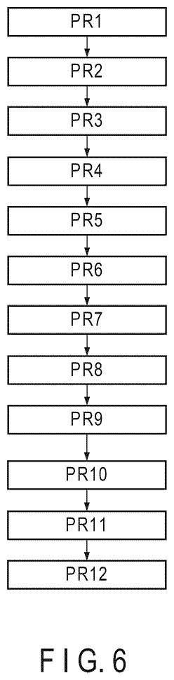

FIG. 6 is a flowchart showing an example of

the manufacturing method of the display device DSP. In the manufacturing of the display device DSP, first, the circuit layer 11 is formed on the substrate 10 (the process PR1 in FIG. 6). Further, the organic insulating layer 12 covering the circuit layer 11 is formed (the process PR2 in FIG. 6).

After the process PR2, the lower electrodes LE1, LE2, and LE3 are formed on the organic insulating layer 12 (the process PR3 in FIG. 6). Further, the rib layer 5 covering the lower electrodes LE1, LE2, and LE3 is formed (the process PR4 in FIG. 6). At this time, the pixel apertures AP1, AP2, and AP3 are not provided in the rib layer 5. The rib layer 5 may be formed by chemical vapor deposition (CVD).

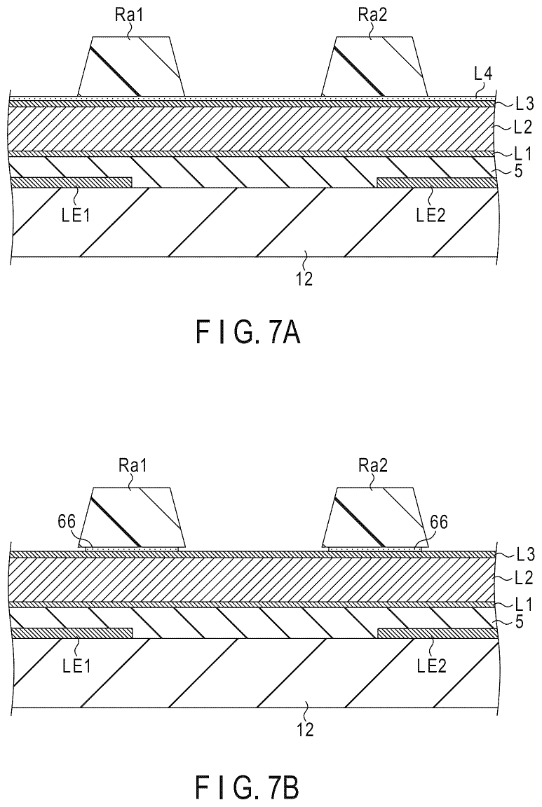

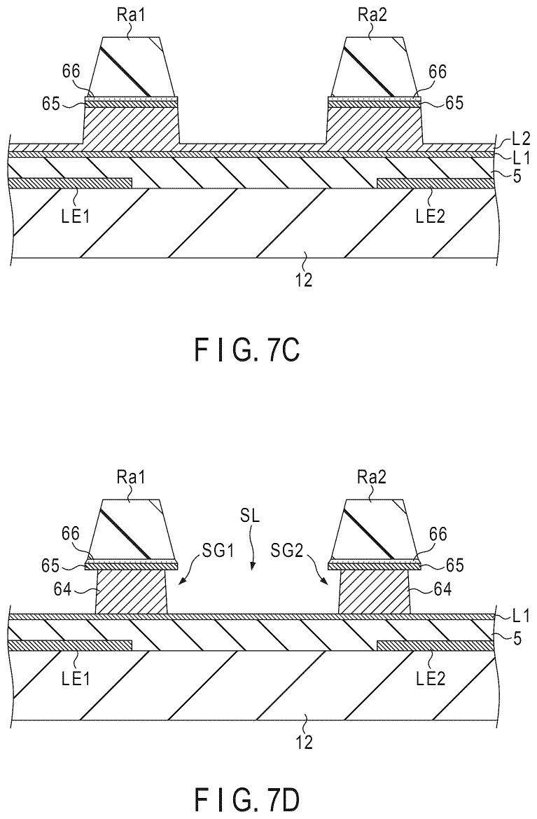

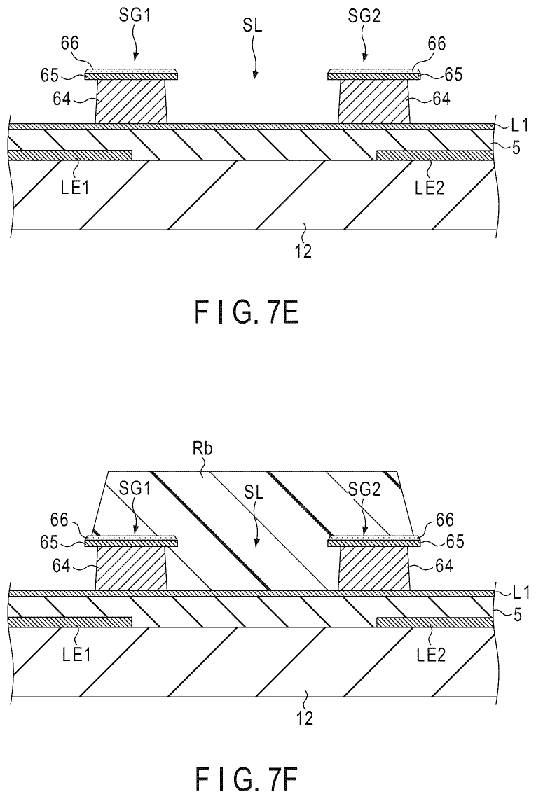

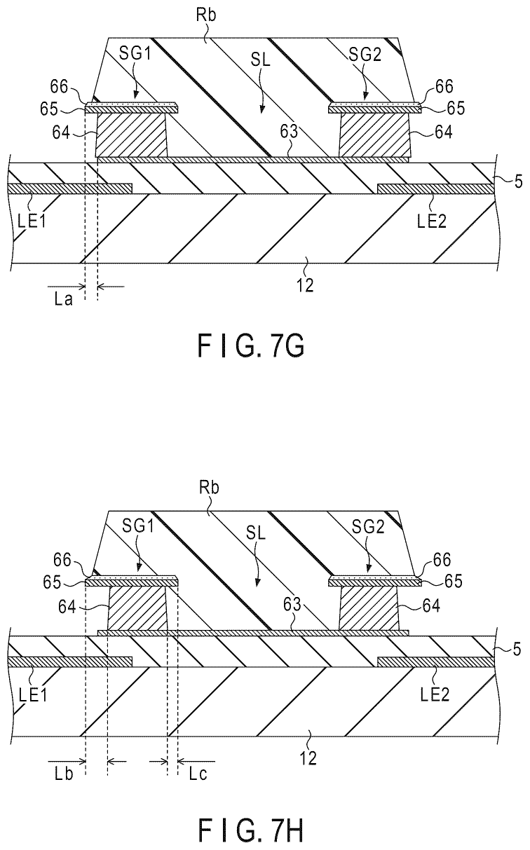

After the formation of the rib layer 5, the partition 6 including the segments SG1, SG2, and SG3 is formed (the process PR5 in FIG. 6). FIG. 7A to FIG. 7I are schematic cross-sectional views showing the first example of the formation method of the partition 6. In the same manner as FIG. 4, these figures show a state where the segments SG1 and SG2 adjacent to each other via the slit SL are formed. FIG. 7A to FIG. 7I omit the illustration of the components under the organic insulating layer 12.

In the formation of the partition 6, as shown in FIG. 7A, first, a first layer L1 to be processed into the bottom layer 63, a second layer L2 to be processed into the stem layer 64, a third layer L3 to be processed into the first top layer 65, and a fourth layer L4 to be processed into the second top layer 66 are formed on the rib layer 5 in order. A resist having a planar shape corresponding to the segments SG1, SG2, and SG3 is further provided on the fourth layer L4. FIG. 7A shows a resist Ral corresponding to the segment SG1 and a resist Ra2 corresponding to the segment SG2.

For example, the first layer L1 is formed of a molybdenum tungsten alloy, the second layer L2 is formed of aluminum, the third layer L3 is formed of titanium, and the fourth layer L4 is formed of an ITO. These layers can be formed by sputtering.

In the example of FIG. 7A, the second layer L2 is thicker than the first layer L1, the third layer L3, and the fourth layer L4. For example, the thickness of the first layer L1 is 50 nm, the thickness of the second layer L2 is 730 nm, the thickness of the third layer L3 is 150 nm, and the thickness of the fourth layer L4 is 50 nm.

Next, etching (for example, wet etching) for the fourth layer L4 is performed as shown in FIG. 7B. This removes the portion exposed from the resists Ral and Ra2 of the fourth layer L4. The portion remaining under the resists Ral and Ra2 of the fourth layer L4 correspond to the second top layers 66 of the segments SG1 and SG2.

After the formation of the second top layer 66, etching (for example, dry etching) for the third layer L3 is performed as shown in FIG. 7C. This removes the portion exposed from the second top layer 66 of the third layer L3. The portions remaining under the second top layer 66 of the third layer L3 correspond to the first top layers 65 of the segments SG1 and SG2. Further, this etching reduces the thickness of the portion exposed from the first top layer 65 of the second layer L2. In the example of FIG. 7C, the widths of the resists Ral and Ra2 are slightly reduced by this etching.

Next, etching (for example, wet etching) for the second layer L2 is performed as shown in FIG. 7D. This removes the portion whose thickness has been reduced of the second layer L2. Furthermore, this reduces the width of the portion under the first top layer 65 of the second layer L2. The portion remaining under the first top layer 65 of the second layer L2 corresponds to the stem layers 64 of the segments SG1 and SG2.

In FIG. 7D, the base forms of the segments SG1 and SG2 having overhang shapes are completed. Further, the slit SL is formed between these segments SG1 and SG2.

Next, the resists Ral and Ra2 are removed (stripped) as shown in FIG. 7E. Next, a resist Rb covering the segments SG1 and SG2 is formed as shown in FIG. 7F. The resist Rb fills the slit SL. That is, the resist Rb covers the side surface on the slit SL side of the stem layer 64 of each of the segments SG1 and SG2. The other side surface of the stem layer 64 is not covered with the resist Rb.

After the formation of the resist Rb, the etching (for example, dry etching) for the first layer L1 is performed as shown in FIG. 7G. This removes the portion exposed from the resist Rb and the stem layer 64 of the first layer L1. The portion remaining under the stem layer 64 and the resist Rb of the first layer L1 corresponds to the bottom layer 63 of the partition 6. This process determines a protrusion length La of the first top layer 65 relative to the end portion of the bottom layer 63 in each of the segments SG1 and SG2. In the example of FIG. 7G, the end portions of the bottom layer 63 are slightly retracted relative to the side surfaces of the stem layer 64.

Next, etching (for example, wet etching) for the stem layer 64 exposed from the resist Rb is performed as shown in FIG. 7H. This etching retracts the side surface of the stem layer 64 exposed from the resist Rb. This process determines a protrusion length Lb of the first top layer 65 relative to the side surface of the stem layer 64 in each of the segments SG1 and SG2.

The side surface on the slit SL side of the stem layer 64 is not subjected to the etching. Thus, a protrusion length Lc of the first top layer 65 relative to the side surface of the stem layer 64 on the slit SL side may be smaller than the protrusion length Lb. After the etching shown in FIG. 7H, the resist Rb is removed (stripped) as shown in FIG. 7I.

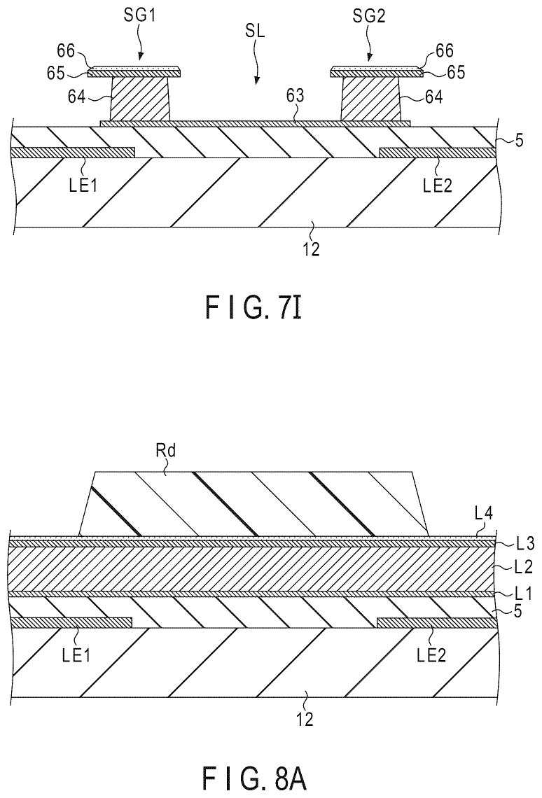

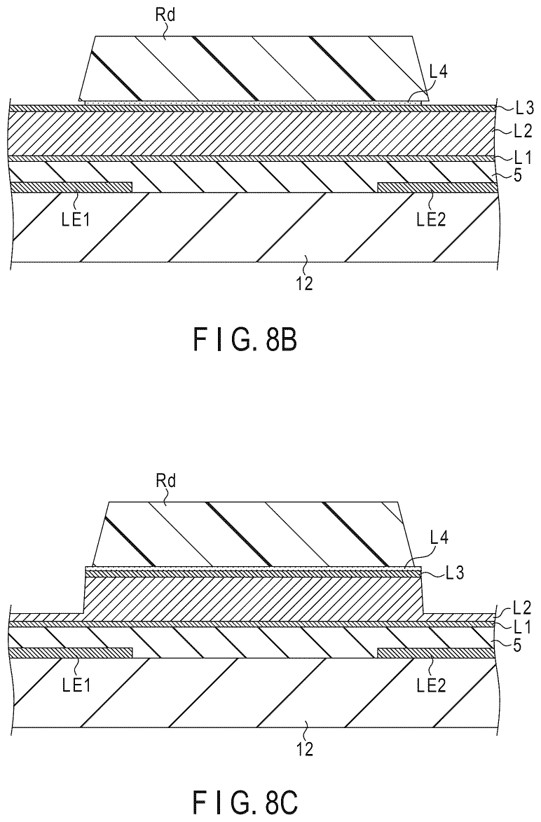

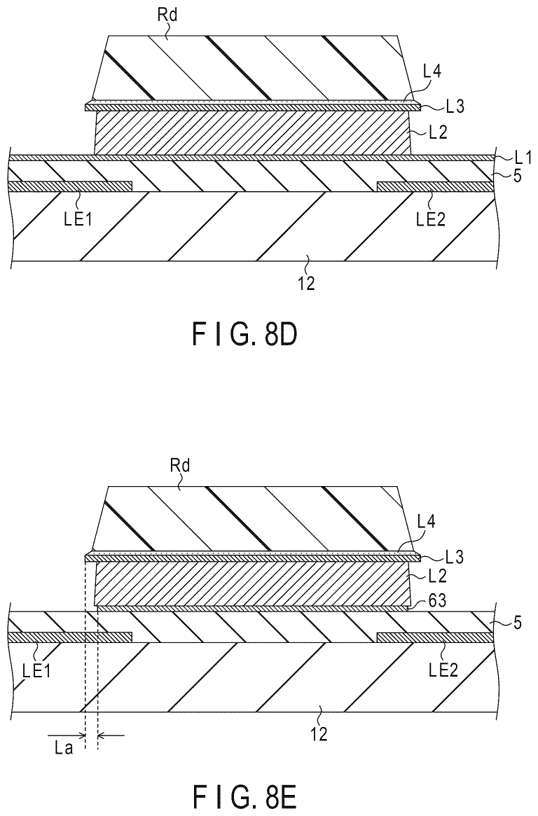

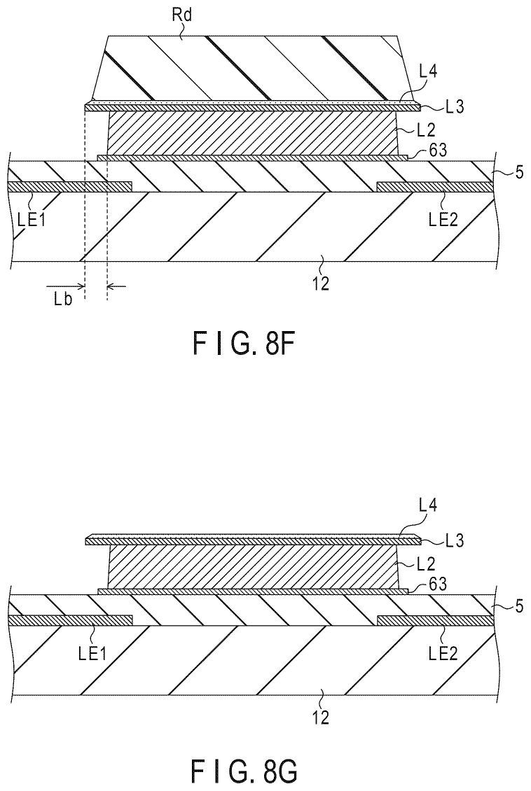

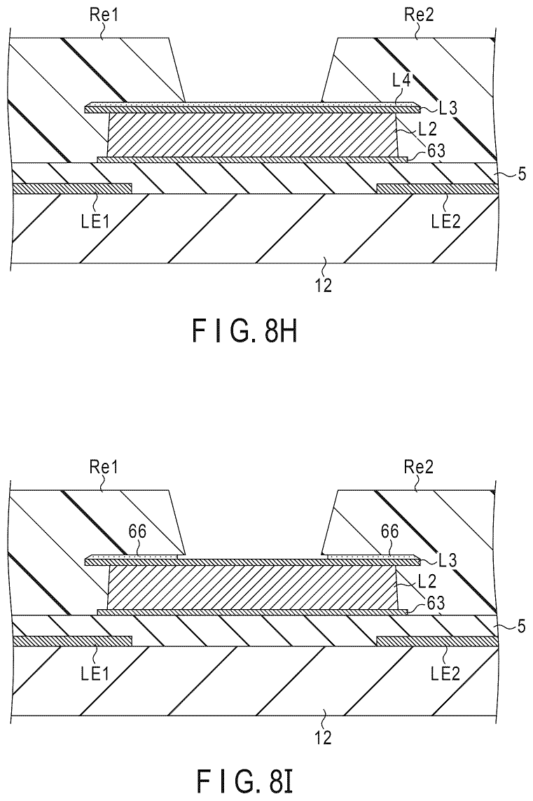

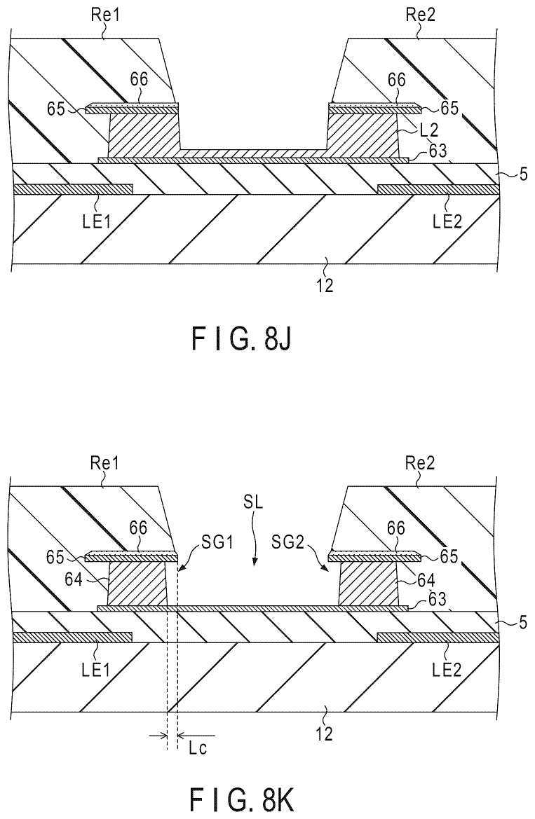

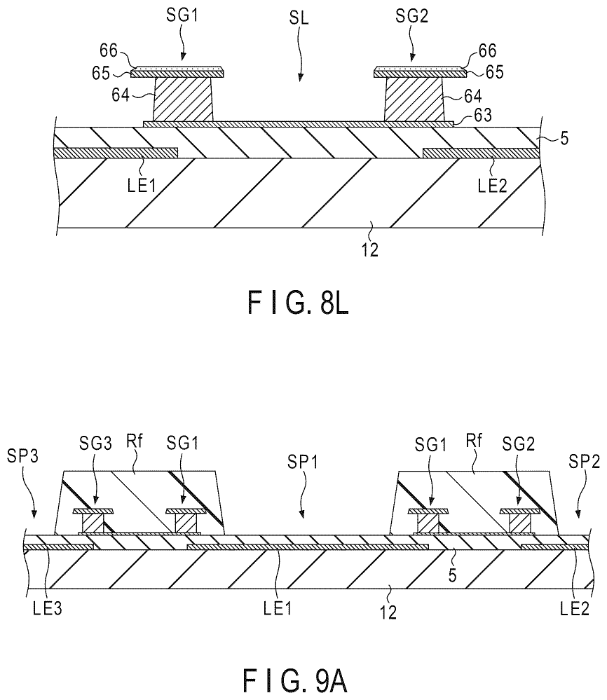

FIG. 8A to FIG. 8L are schematic cross-sectional views showing a second example of the formation method of the partition 6. In the same manner as FIG. 7A to FIG. 7I, these figures show a state where the segments SG1 and SG2 adjacent to each other via the slit SL are formed.

In the second example as well, the first layer L1, the second layer L2, the third layer L3, and the fourth layer L4 are formed on the rib layer 5 in order as shown in FIG. 8A. Further, a resist Rd is formed on the fourth layer L4. The resist Rd has a planar shape corresponding to the entire partition 6 including the segments SG1, SG2, and SG3 and the slit SL.

Next, etching (for example, wet etching) for the fourth layer L4 is performed as shown in FIG. 8B. This removes the portion exposed from the resist Rd of the fourth layer L4.

Further, etching (for example, dry etching) for the third layer L3 is performed as shown in FIG. 8C. This removes the portion exposed from the fourth layer L4 of the third layer L3. This etching removes the thickness of the portion exposed from the third layer L3 of the second layer L2. This slightly reduces the width of the resist Rd as well.

Next, etching (for example, wet etching) for

the second layer L2 is performed as shown in FIG. 8D. This removes the portion whose thickness has been reduced of the second layer L2. Further, the width of the portion under the third layer L3 of the second layer L2 is reduced.

Further, etching (for example, dry etching) for the first L1 is performed as shown in FIG. 8E. This removes the portion exposed from the second layer L2 of the first layer L1. The portion remaining under the second layer L2 of the first layer L1 corresponds to the bottom layer 63 of the partition 6. This process determines the same protrusion length La as the one shown in FIG. 7G. In the example of FIG. 8E, the end portion of the bottom layer 63 is slightly retracted relative to the side surface of the second layer L2.

Next, etching (for example, wet etching) for the second layer L2 is performed as shown in FIG. 8F. This etching retracts the side surface of the second layer L2. This process determines the same protrusion length Lb as the one shown in FIG. 7H.

After this etching, the resist Rd is removed (stripped) as shown in FIG. 8G. Further, resists Re1 and Re2 are formed as shown in FIG. 8H. The resist Re1 has a shape corresponding to the outer shape of the segment SG1. The resist Re2 has a shape corresponding to the outer shape of the segment SG2.

After the formation of the resists Re1 and Re2, the etching (for example, wet etching) for the fourth layer L4 is performed as shown in FIG. 8I. This removes the portion exposed from the resists Rel and Re2 of the fourth layer L4. The portions remaining under the respective resists Rel and Re2 of the first layer L1 correspond to the second top layers 66 of the segments SG1 and SG2.

Further, etching (for example, dry etching) for the third layer L3 is performed as shown in FIG. 8J. This removes the portion exposed from the second top layer 66 of the third layer L3. The portions remaining under the second top layer 66 of the third layer L3 correspond to the first top layers 65 of the segments SG1 and SG2. Further, this etching reduces the thickness of the portion exposed from the resists Rel and Re2 and the first top layer 65 of the second layer L2. In the example of FIG. 8J, the end portions of the resists Re1 and Re2 are slightly retracted by this etching.

Next, etching (for example, wet etching) for the second layer L2 is performed as shown in FIG. 8K. This removes the portion whose thickness has been reduced of the second layer L2. Furthermore, this reduces the width of the portion under the first top layer 65 of the second layer L2. The portion remaining under the first top layer 65 of the second layer L2 corresponds to the stem layers 64 of the segments SG1 and SG2. This process determines the same protrusion length Lc as the one shown in FIG. 7H.

After the etching shown in FIG. 8K, the resists Rel and Re2 are removed (stripped) as shown in FIG. 8L. This completes the segments SG1 and SG2.

The first example shown in FIG. 7A to FIG. 7I and the second example shown in FIG. 8A to FIG. 8L show the formation of the segments SG1 SG2. Note that the segment SG3 is also formed in these processes. The partition 6 is not limited to the first and second examples, and may be formed in other methods.

After the formation of the partition 6, the pixel apertures AP1, AP2, and AP3 are formed in the rib layer 5 (the process PR6 in FIG. 6). Further, the display elements DE1, DE2, and DE3 are formed (the processes PR7, PR8, and PR9 in FIG. 6).

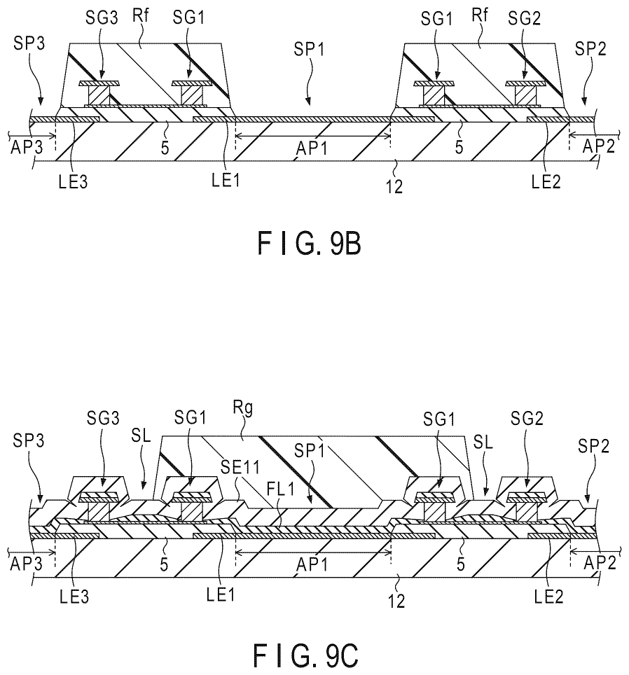

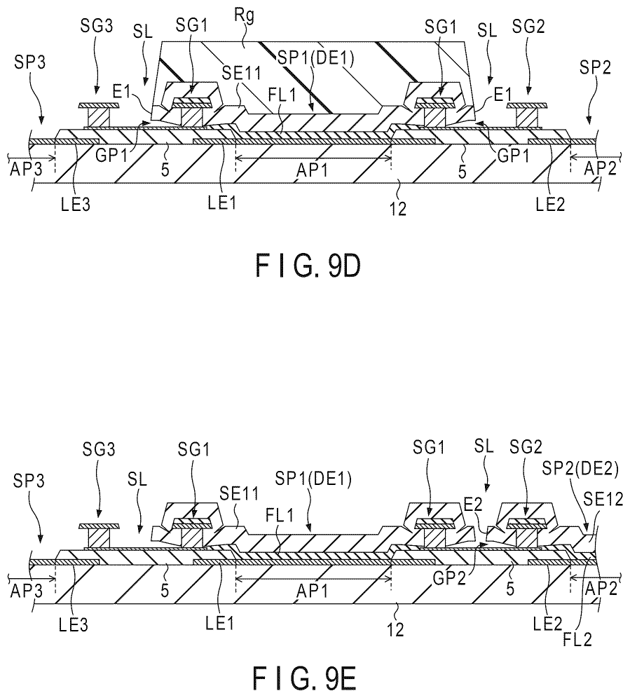

FIG. 9A to FIG. 9F are schematic cross-sectional views showing processes of forming the pixel apertures AP1, AP2, and AP3 and the display elements DE1, DE2, and DE3. In the formation of the pixel apertures AP1, AP2, and AP3, a resist Rf covering the segments SG1 and SG2 and the slit SL is formed as shown in FIG. 9A. Further, the etching for the rib layer 5 using this resist Rf as a mask forms the pixel apertures AP1, AP2, and AP3 as shown in FIG. 9B. After this etching, the resist Rf is removed (stripped).

In the formation of the display element DE1, the stacked film FL1 and the sealing layer SE11 are formed first as shown in FIG. 9C. As shown in FIG. 3, the stacked film FL1 includes, the organic layer OR1 contacting the lower electrode LE1 through the pixel aperture AP1, the upper electrode UE1 covering the organic layer OR1, and the cap layer CP1 covering the upper electrode UE1. For example, the organic layer OR1, the upper electrode UE1, and the cap layer CP1 may be formed by vapor deposition. For example, the sealing layer SE11 may be formed by CVD.

The stacked film FL1 and the sealing layer SE11 are formed in the entire display area DA and surrounding area SA. The stacked film FL1 is separated by the segments SG1, SG2, and SG3 having overhang shapes. The sealing layer SE11 continuously covers the portions into which the stacked film FL1 is separated and the segments SG1, SG2, and SG3.

Subsequently, the stacked film FL1 and the sealing layer SE11 are patterned. In this patterning, a resist Rg is provided on the sealing layer SE11 as shown in FIG. 9C. The resist Rg covers the subpixel SP1, the segment SG1, and part of the slit SL.

Subsequently, an etching process using the resist Rg as a mask is performed. This etching process removes the portions exposed from the resist Rg of the respective stacked film FL1 and sealing layer SE11 as shown in FIG. 9D. This process forms the display element DE1 in the subpixel SP1. This etching process may include wet etching and dry etching performed in order for the sealing layer SE11, the cap layer CP1, the upper electrode UE1, and the organic layer OR1. After these etching processes, the resist Rg is removed (stripped).

As shown in FIG. 9D, the end portion E1 of the sealing layer SE11 is located in the slit SL. The portion under the end portion E1 of the stacked film FL1 may be eliminated by the etching. This forms the gap GP1.

The display element DE2 is formed by the same process as that of the display element DE1. That is, the stacked film FL2 and the sealing layer SE12 are formed first in the entire display area DA and surrounding area SA. The stacked film FL2 includes the organic layer OR2 contacting the lower electrode LE2 through the pixel aperture AP2, the upper electrode UE2 covering the organic layer OR2, and the cap layer CP2 covering the upper electrode UE2 as shown in FIG. 3. The organic layer OR2, the upper electrode UE2, and the cap layer CP2 may be formed by, for example, vapor deposition. The sealing layer SE12 may be formed by, for example, CVD.

Subsequently, the stacked film FL2 and the sealing layer SE12 are patterned. This process forms the display element DE2 in the subpixel SP2 as shown in FIG. 9E. In FIG. 9E, the end portion E2 of the sealing layer SE12 is located in the slit SL. The stacked film FL2 under the end portion E2 may be eliminated by the etching. This forms the gap GP2.

The display element DE3 is formed by the same processes as those of the display elements DE1 and DE2.

That is, the stacked film FL3 and the sealing layer SE13 are formed first in the entire display area DA and surrounding area SA. The stacked film FL3 includes, the organic layer OR3 contacting the lower electrode LE3 through the pixel aperture AP3, the upper electrode UE3 covering the organic layer OR3, and the cap layer CP3 covering the upper electrode UE3 as shown in FIG. 3. The organic layer OR3, the upper electrode UE3, and the cap layer CP3 may be formed by, for example, vapor deposition. The sealing layer SE13 may be formed by, for example, CVD.

Subsequently, the stacked film FL3 and the sealing layer SE13 are patterned. This process forms the display element DE3 in the subpixel SP3 as shown in FIG. 9F. In FIG. 9F, the end portion E3 of the sealing layer SE13 is located in the slit SL. The stacked film FL3 under the end portion E3 may be eliminated by the etching. This forms the gap GP3.

Here, the above description assumes that the display elements DE1, DE2, and DE3 are formed in this order. However, the display elements DE1, DE2, and DE3 may be formed in another order.

After the process PR9, the resin layer RS1 is formed (the process PR10 in FIG. 6). After the process PR10, the sealing layer SE2 covering the resin layer RS1 is formed by, for example, CVD (the process PR11 in FIG. 6). Further, the resin layer RS2 covering the sealing layer SE2 is formed (the process PR12 in FIG. 6). The resin layers RS1 and RS2 may be formed by, for example, the ink-jet method.

These processes achieve the display device DSP with the configuration shown in FIG. 1 to FIG. 5. The manufacturing method of the display device DSP is not limited to these examples and may be appropriately changed.

The present embodiment described above can improve the yield of the display device DSP. The following describes this effect in detail.

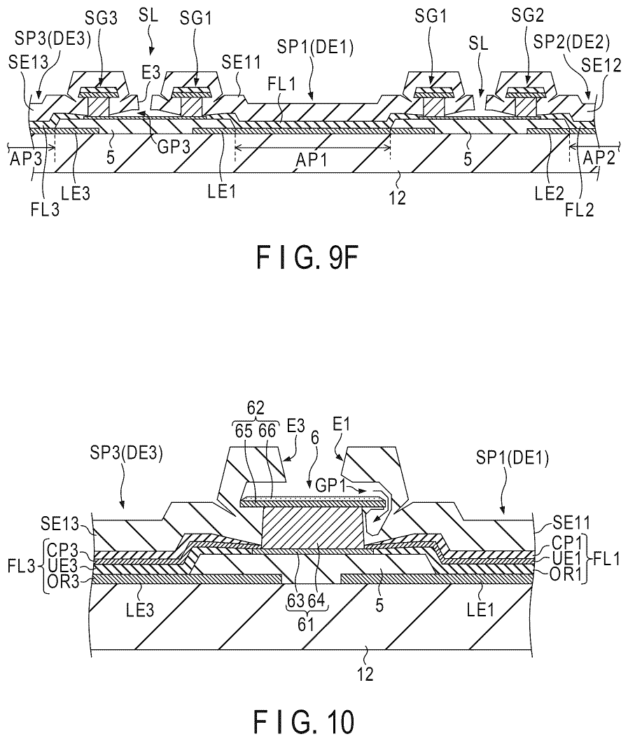

FIG. 10 is a schematic cross-sectional view of a configuration of a comparative example for the present embodiment. This figure focuses on the vicinity of the boundary between the subpixels SP1 and SP3 in the same manner as FIG. 5. In the comparative example, the stem layer 64 and the upper portion 62 of the partition 6 are not separated by the segments SG1, SG2, and SG3. Thus, one partition 6 having an overhang shape is provided between the subpixels SP1 and SP3. The end portions E1 and E3 of the respective sealing layers SE11 and SE13 are located above the partition 6.

In the comparative example as well, the gap GP1 is formed under the end portion E1. This gap GP1 is formed by the etching process shown in FIG. 9D eliminating the portion under the end portion E1 of the stacked film FL1. The gap GP1 may be spread by etching gas of the dry etching and etchant of the wet etching included in the etching process in the formation of the display elements DE2 and DE3.

In FIG. 10, the gap GP1 reaches the vicinity of the stacked film FL1 constituting the display element DE1. Further spreading of the gap GP1 may form a path reaching the stacked film FL1. If this path is formed, the stacked film FL1 may be damaged in the following etching processes and cleaning processes.

In contrast, in the present embodiment, the partition 6 has the segments SG1, SG2, and SG3 separated by the slit SL. As shown, for example, in FIG. 5, the end portion E1 of the sealing layer SE11 is located in the slit SL1. That is, the segment SG1 having an overhang shape is interposed between the gap GP1 and the stacked film FL1 constituting the display element DE1. This configuration makes it hard for the gap GP1 to reach the stacked film FL1 constituting the display element DE1 even when the gap GP1 is spread by the etching process in the formation of the display elements DE2 and DE3.

In this manner, the present embodiment suppresses the occurrence of the situation described with reference to the comparative example and thus is capable of selecting etching conditions with strong isotropy and extending the etching time in etching for the display elements DE1, DE2, and DE3. This suppresses the occurrence of residues due to insufficient etching and thus can manufacture reliable display devices DSP.

In the present embodiment, the bottom layer 63 having conductivity is provided under the segments SG1, SG2, and SG3. This bottom layer 63 is not separated by the slit SL. This configuration can supply the segments SG1, SG2, and SG3 with common voltage through the bottom layer 63. This eliminates the need for providing the configuration for supplying the segments SG1, SG2, and SG3 with power from the circuit layer 11 in the display area DA.

### Second Embodiment

The following describes the second embodiment. Configurations that are not particularly referred to may adopt the same configurations as those of the first embodiment.

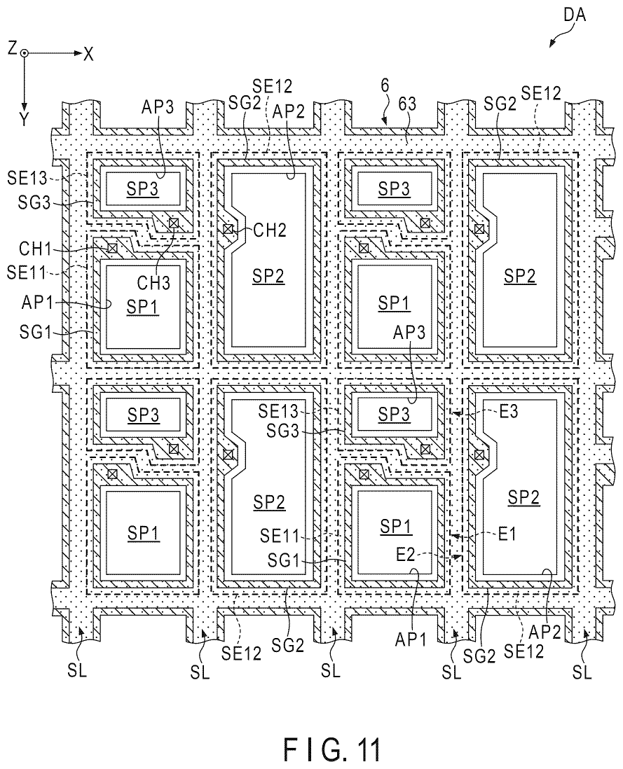

FIG. 11 is a schematic plan view of the display area DA of the display device DSP according to the second embodiment. In the same manner as FIG. 2, this figure shows the area corresponding to four pixels PX. In the present embodiment, one segment SG2 is provided in each subpixel SP2. Each segment SG2 surrounds the subpixel SP2. The segments SG2 adjacent to each other in the Y-direction are spaced apart from each other via the slit SL. That is, the segment SG2 is surrounded by the slit SL.

For example, in the same manner as the example of FIG. 4, the segment SG2 comprises the stem layer 64, the first top layer 65, and the second top layer 66. The bottom layer 63 is provided under the stem layer 64 of the segment SG2. The bottom layer 63 is not separated by the slit SL between the segments SG2 adjacent to each other in the Y-direction and overlaps this slit SL in plan view.

In the present embodiment, the sealing layers SE12 of the subpixels SP2 are independent from each other. For example, the end portion E2 of each sealing layer SE12 is located in the slit SL over its whole circumference.

Even in the configuration of the present embodiment, effects similar to those of the first embodiment can be obtained. Providing the independent segment SG2 and sealing layer SE12 in each of the plurality of subpixel SP2 can individually and sufficiently seal the display element DE2 in each subpixel SP2.

### Third Embodiment

The following describes the second embodiment. Configurations that are not particularly referred to may adopt the same configurations as those of the first embodiment.

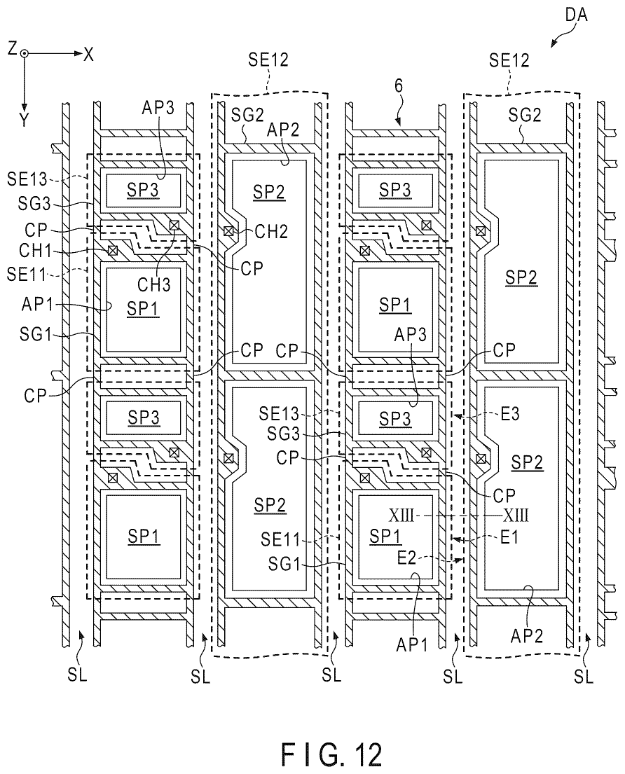

FIG. 12 is a schematic plan view of the display area DA of the display device DSP according to the third embodiment. In the same manner as FIG. 2, this figure shows the area corresponding to four pixels PX. In the present embodiment, the partition 6 comprises a connection portion CP connecting the segments SG1 and SG3 arranged in the Y-direction to each other.

In the example of FIG. 12, the segments SG1 and SG3 are connected to each other by two connection portions CP. For example, these connection portions CP connect both end portions in the X-direction of the segments SG1 and SG3. The number and the layout of the connection portions CP connecting the segments SG1 and SG3 are not limited to the example of FIG. 12.

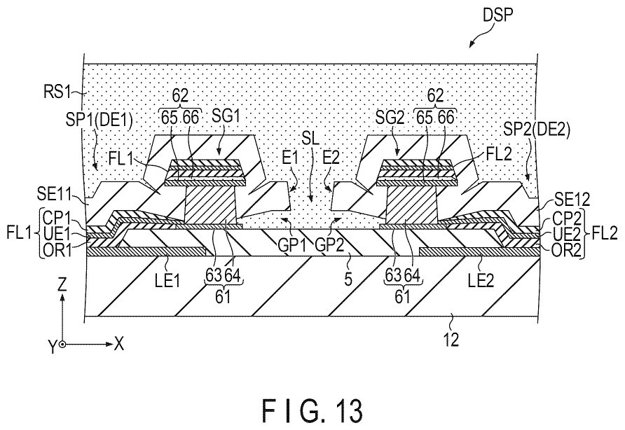

FIG. 13 is a schematic cross-sectional view showing the display device DSP along the XIII-XIII line of FIG. 12. In the present embodiment, the bottom layer 63 is separated by the slit SL between the segments SG1 and SG2. In the slit SL, the resin layer RS1 covers the rib layer 5.

In the same manner as the example of FIG. 13, the bottom layer 63 is separated by the slit SL between the segments SG1 and SG3. Further, the bottom layer 63 is separated by the slit SL between the segments SG2 and SG3.

A conductor constituted by the segments SG1 and SG2 connected to each other by the connection portion CP is supplied with common voltage through a power supply unit, provided, for example, in the surrounding area SA. This point applies to the segments SG3 as well.

In the present embodiment as well, the same advantageous effect as the first embodiment can be obtained. Further, the bottom layer 63 is not provided in the slit SL. Thus, transmittance in the slit SL can be increased. This configuration is advantageous, for example, for cases where an optical sensor is provided on the rear side of the display device DSP.

In the example shown in FIG. 12, the segment SG2 separated per the subpixel SP2 may be provided in the same manner as the second embodiment. In this case, the segments SG2 adjacent to each other in the Y-direction may be connected to each other by the connection portion CP.

### Fourth Embodiment

The following describes the fourth embodiment. Configurations that are not particularly referred to may adopt the same configurations as those of the above embodiments.

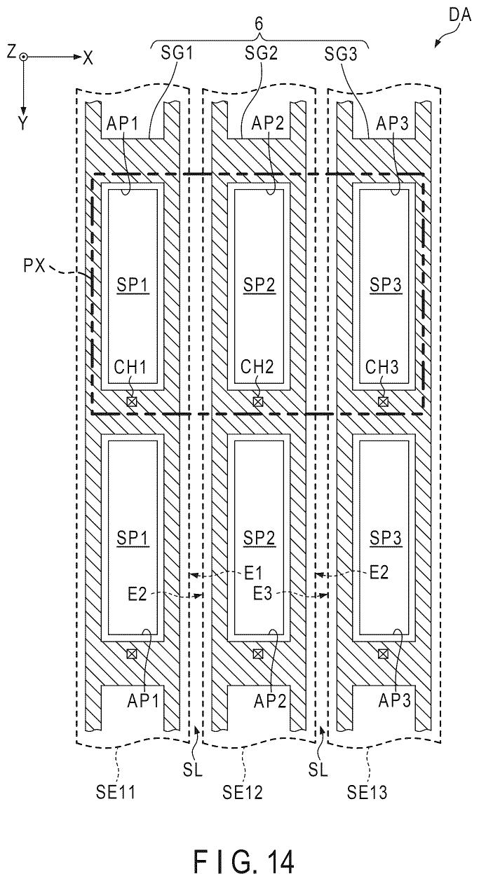

FIG. 14 is a schematic plan view of the display area DA of the display device DSP according to the fourth embodiment. In the present embodiment, the plurality of subpixels SP1 are arranged in the Y-direction, the plurality of subpixels SP2 are arranged in the Y-direction, and the plurality of subpixels SP3 are arranged in the Y-direction. For example, one pixel PX is constituted by the subpixels SP1, SP2, and SP3 arranged in the X-direction.

In the same manner as the above embodiments, the partition 6 comprises the segments SG1, SG2, and SG3. Further, the slit SL is formed between the segments SG1, SG2, and SG3.

The sealing layer SE11 is formed across the plurality of subpixels SP1 arranged in the Y-direction. The sealing layer SE12 is formed across the plurality of subpixels SP2 arranged in the Y-direction. The sealing layer SE13 is formed across the plurality of subpixels SP3 arranged in the Y-direction. The end portions E1, E2, and E3 of the respective sealing layers SE11, SE12, and SE13 are located in the slit SL.

The same configurations as those of the above embodiments can be applied to the segments SG1, SG2, and SG3. For example, the bottom layer 63 may not be separated by the slit SL in the same manner as the first embodiment, or may be separated by the slit SL in the same manner as the third embodiment.

Effects similar to those of the above embodiments can be also obtained from the configuration of the present embodiment. In addition to those disclosed in the present embodiment and each of the above embodiments, various layouts can be applied to the subpixels SP1, SP2, and SP3.

### Fifth Embodiment

The following describes the fifth embodiment. Configurations that are not particularly referred to may adopt the same configurations as those of the above embodiments.

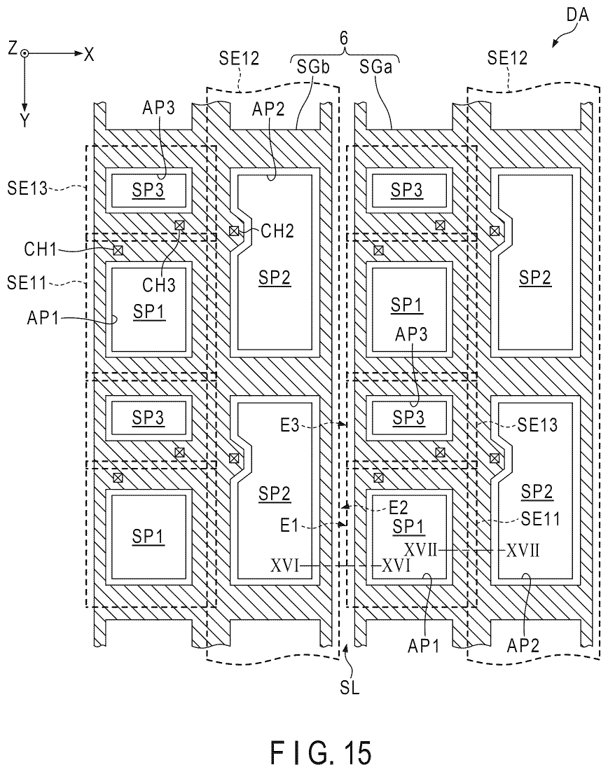

FIG. 15 is a schematic plan view of the display area DA of the display device DSP according to the fifth embodiment. The layout of the subpixels SP1, SP2, and SP3 shown in FIG. 15 is the same as the one shown in FIG. 2 in the first embodiment. In the present embodiment, the partition 6 has segments SGa and SGb (the first and second segments) separated by the slit SL extending in the Y-direction. The segment SGa surrounds the plurality of subpixels SP1 and SP3 arranged in the Y-direction and the plurality of subpixels SP2 arranged in the Y-direction. Similarly, the segment SGb surrounds the plurality of subpixels SP1 and SP3 arranged in the Y-direction and the plurality of subpixels SP2 arranged in the Y-direction.

In the example of FIG. 15, the sealing layer SE12 extends across the plurality of subpixels SP2 arranged in the Y-direction. Further, the end portions of the sealing layers SE11 and SE12 adjacent to each other without the interposition of the slit SL overlap, the end portions of the sealing layers SE12 and SE13 adjacent to each other without the interposition of the slit SL overlap, and the end portions of the sealing layers SE11 and SE13 adjacent to each other in the Y-direction overlap.

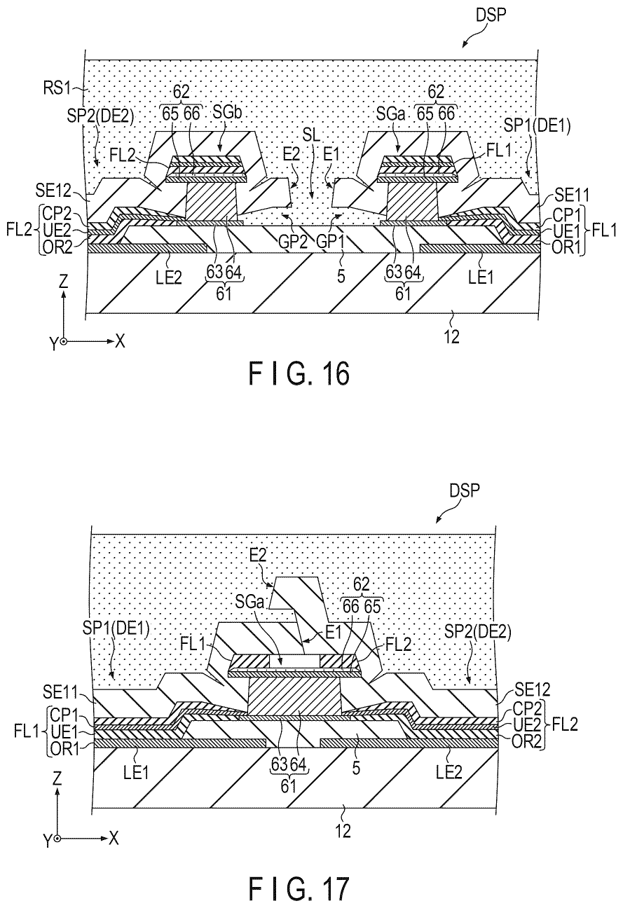

FIG. 16 is a schematic cross-sectional view of the display device DSP along the XVI-XVI line of FIG. 15. In the same manner as the segments SG1, SG2, and SG3 in each of the embodiments, each of the segments SGa and SGb comprises the stem layer 64, the first top layer 65, and the second top layer 66. The bottom layer 63 is provided under the segments SGa and SGb. In the example of FIG. 16, the bottom layer 63 is separated by the slit SL.

The end portions E1 and E2 of the respective sealing layers SE11 and SE12 are located in the slit SL. In the example of FIG. 16, the end portions E1 and E2 are spaced apart from each other in the X-direction. As another example, the end portions E1 and E2 may contact. The gaps GP1 and GP2 are formed under the respective end portions E1 and E2.

FIG. 17 is a schematic cross-sectional view of the display device DSP along the XVII-XVII line of FIG. 15. In the position shown in this cross-sectional view, the end portions E1 and E2 of the respective sealing layers SE11 and SE12 are located above the partition 6. Further, the end portion E2 is located above the end portion E1.

In the example of FIG. 17, the stacked film FL1 is provided between the upper portion 62 and the sealing layer SE11. The stacked film FL2 is provided between the upper portion 62 and the sealing layer SE12. The configuration is not limited to this example. The stacked films FL1 and FL2 may not be provide between the upper portion 62 and the sealing layers SE11 and SE12.

The configuration in the vicinity of the subpixels SP2 and SP3 arranged in the X-direction via the slit SL is the same as the one shown in FIG. 16. The configuration in the vicinity of the boundary between the subpixels SP2 and SP3 arranged in the X-direction without the interposition of the slit SL and the configuration in the vicinity of the boundary between the subpixels SP1 and SP2 arranged in the Y-direction are the same as those shown in FIG. 17.

The cross-sectional structure in FIG. 16 is the same as those shown in FIG. 4 and FIG. 5 in the first embodiment. Thus, in the same manner as the first embodiment, the damage of the sealing layer SE11 reaching the display element DE1 is suppressed in the vicinity of the slit SL in the etching process in the formation of the display elements DE2 and DE3.

In the present embodiment, the end portion E1 of the sealing layer SE11 overlap the end portions E2 and E3 of the sealing layers SE12 and SE13 in the position where the slit SL is not provided. Thus, the vicinity of the end portion E1 of the sealing layer SE11 is protected by the sealing layers SE12 and SE13 and the damage of the sealing layer SE11 shown in the comparative example is suppressed in the etching process in the formation of the display elements DE2 and DE3. Thus, in the above-described embodiments, the display device DSP in which the display element DE1 is sufficiently sealed by the sealing layer SE11 can be achieved.

### Sixth Embodiment

The following describes the sixth embodiment. Configurations that are not particularly referred to may adopt the same configurations as those of the above embodiments.

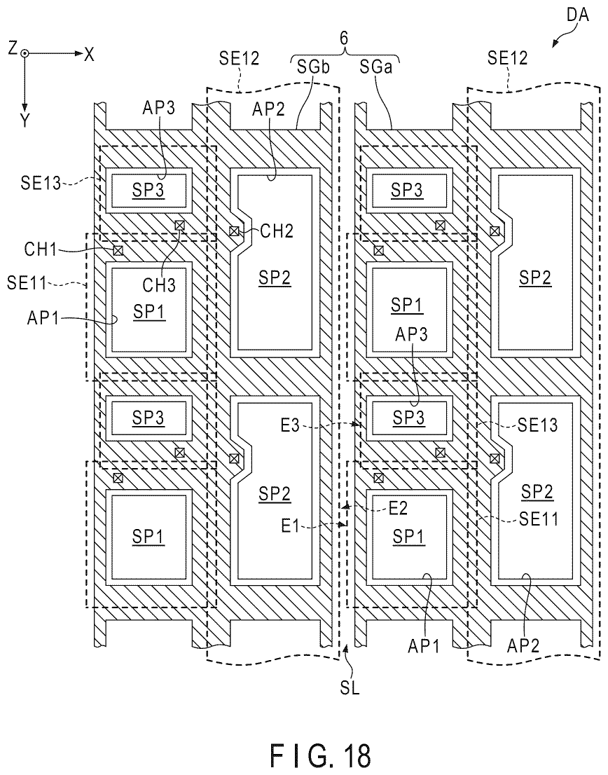

FIG. 18 is a schematic plan view of the display area DA of the display device DSP according to the sixth embodiment. The configuration shown in FIG. 18 is approximately equivalent to the one shown in FIG. 15. However, in FIG. 18, the sealing layer SE13 does not overlap the slit SL. The end portion E3 of the sealing layer SE13 is located above the partition 6 (above the segments SGa and SGb).

Even in the configuration of the present embodiment, effects similar to those of the fifth embodiment can be obtained. Further, the configuration of the present embodiment can increase the transparency of the slit SL by the sealing layer SE13 not overlapping the slit SL. The sealing layer SE13 is formed after the formation of the sealing layers SE11 and SE12. Thus, the above-described damage in the sealing layer SE11 is less likely to occur in the sealing layer SE13.

In each of the above embodiments, the term “partition” includes various overhanging structures. Even if the overhanging structure has a shape different from the partition disclosed in each embodiment, the portion protruding laterally corresponds to the “upper portion” and the portion recessed below of the portion corresponds to the “lower portion”.

The display device DSP may further comprise a plurality of dummy pixels provided around the display area DA. The configuration of the display area DA disclosed in each embodiment can also be applied to the dummy pixel area including these dummy pixels.

All of the display devices that can be implemented by a person of ordinary skill in the art through arbitrary design changes to the display device disclosed as each embodiment described above come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device, comprising:
a first subpixel and a second subpixel;
a partition including a first segment surrounding the first subpixel and a second segment surrounding the second subpixel;
a first stacked film provided in the first subpixel and including an electrode electrically connected to the first segment;
a second stacked film provided in the second subpixel and including an electrode electrically connected to the second segment;
a first sealing layer formed of an inorganic insulating material and covering the first stacked film; and
a second sealing layer formed of an inorganic insulating material and covering the second stacked film, wherein
the first segment and the second segment are separated by a slit, and
the first sealing layer overlaps at least part of the slit in plan view.

2. The display device of claim 1, wherein
the second sealing layer overlaps at least part of the slit in plan view.

3. The display device of claim 1, wherein
the partition further comprises a bottom layer overlapping the first segment, the second segment, and the slit in plan view,
each of the first segment and the second segment comprises:
a stem layer provided on the bottom layer; and
an upper portion provided on the stem layer and having an end portion protruding relative to a side surface of the stem layer, and
the stem layer and the upper portion of the first segment are spaced apart from the stem layer and the upper portion of the second segment in the slit.

4. The display device of claim 1, wherein
the first segment is surrounded by the slit.

5. The display device of claim 4, wherein
an end portion of the first sealing layer is located in the slit over its whole circumference.

6. The display device of claim 4, further comprising:
a plurality of second subpixels including the second subpixel, wherein
the second segment surrounds each of the plurality of second subpixels, and
the second sealing layer continuously covers the plurality of second subpixels.

7. The display device of claim 4, wherein
the second segment is surrounded by the slit.

8. The display device of claim 7, wherein
an end portion of the second sealing layer is located in the slit over its whole circumference.

9. The display device of claim 1, further comprising:
a third subpixel;
a third stacked film provided in the third subpixel and including an electrode electrically connected to the partition; and
a third sealing layer formed of an inorganic insulating material and covering the third stacked layer, wherein
the partition further includes a third segment surrounding the third subpixel.

10. The display device of claim 9, wherein
the third segment is surrounded by the slit, and
an end portion of the third sealing layer is located in the slit over its whole circumference.

11. The display device of claim 9, wherein
the partition further comprises a bottom layer overlapping the first segment, the second segment, and the third segment in plan view,
each of the first to third segments comprises:
a stem layer provided on the bottom layer; and
an upper portion provided on the stem layer and having an end portion protruding relative to a side surface of the stem layer, and
in the slit, the bottom layer is separated, the stem layers of the first to third segments are spaced apart from one another, and the upper portions of the first to third segments are spaced apart from one another.

12. The display device of claim 11, wherein
the partition has a connection portion connecting the first segment and the third segment to each other.

13. The display device of claim 9, wherein
the first subpixel and the second subpixel are arranged in a first direction, and
the first subpixel and the third subpixel are arranged in a second direction intersecting the first direction.

14. The display device of claim 9, wherein
the first subpixel, the second subpixel, and the third subpixel are arranged in the first direction.

15. A display device, comprising:
a first subpixel and a second subpixel;
a partition including a first segment surrounding the first subpixel and a second segment surrounding the second subpixel;
a first stacked film provided in the first subpixel and including an electrode electrically connected to the first segment;
a second stacked film provided in the second subpixel and including an electrode electrically connected to the second segment;
a first sealing layer formed of an inorganic insulating material and covering the first stacked film; and
a second sealing layer formed of an inorganic insulating material and covering the second stacked film, wherein
the first segment and the second segment are separated by a slit,
the first sealing layer has a first end portion located inside the slit, and
a first gap is formed under the first end portion.

16. The display device of claim 15, further comprising:
a resin layer covering the first sealing layer and the second sealing layer, wherein
at least part of the first gap is filled with the resin layer.

17. The display device of claim 15, wherein
the second sealing layer has a second end portion located inside the slit.

18. The display device of claim 17, wherein
a second gap is formed under the second end portion.

19. The display device of claim 18, further comprising:
a resin layer covering the first sealing layer and the second sealing layer, wherein
at least part of the second gap is filled with the resin layer.

20. The display device of claim 15, wherein
the partition further comprises a bottom layer overlapping the first segment, the second segment, and the slit in plan view,
each of the first segment and the second segment comprises:
a stem layer provided on the bottom layer; and
an upper portion provided on the stem layer and having an end portion protruding relative to a side surface of the stem layer, and
the stem layer and the upper portion of the first segment are spaced apart from the stem layer and the upper portion of the second segment in the slit.
